(19) United States
(12) Patent Application Publication
(10) Pub. No.: US 2013/0092964 A1
(43) Pub. Date: Apr. 18, 2013

(54) HIGHLY RELIABLE PHOTOLUMINESCENT MATERIALS HAVING A THICK AND UNIFORM TITANIUM DIOXIDE COATING

(71) Applicants: Yi-Qun Li, Danville, CA (US); Xufang Chen, Newak, CA (US); Yuming Xie, Sugar Land, TX (US)

(72) Inventors: Yi-Qun Li, Danville, CA (US); Xufang Chen, Newak, CA (US); Yuming Xie, Sugar Land, TX (US)

(73) Assignee: Intematix Corporation, Fremont, CA (US)

(21) Appl. No.: 13/273,166

(22) Filed: Oct. 13, 2011

(51) Int. Cl. H01L 33/50; B05D 5/06; C09K 11/67

(52) U.S. Cl. 257/98; 252/301.4 F; 252/301.4 S; 427/162; 257/E33.061; 977/742

(57) ABSTRACT

Described herein are coated photoluminescent materials and methods for preparing such coated photoluminescent materials. More particularly, provided herein are phosphors coated with titanium dioxide, methods for preparing phosphors coated with titanium dioxide, and solid-state light emitting devices which include phosphors coated with titanium dioxide.

### TECHNICAL FIELD

Provided herein are coated photoluminescent materials and methods for preparing such coated photoluminescent materials. More particularly, although not exclusively, provided herein are phosphors coated with titanium dioxide, methods for preparing phosphors coated with titanium dioxide, and solid-state light emitting devices which include phosphors coated with titanium dioxide.

### BACKGROUND

Photoluminescent materials are integral components of white Light Emitting Diodes (LEDs) which are typically used as backlight sources of various display sources including, for example, mobile phones and liquid crystal display devices. More recently, white-light-emitting LEDs using photoluminescent materials have been extensively used in lighting and have been proposed as substitutes for conventional white light sources such as incandescent, fluorescent and halogen lamps.

A problem with many photoluminescent materials is their sensitivity to heat, oxygen and moisture which impacts the lifetime and/or utility of devices employing these materials. Accordingly, what is needed are novel photoluminescent materials which are more stable to heat, oxygen and moisture than currently available photo

### SUMMARY

The teaching herein satisfies these and other needs by providing coated photoluminescent materials which possess superior stability to heat and moisture, methods for making these coated photoluminescent materials, and LED devices incorporating these coated photoluminescent materials. In one aspect, a coated photoluminescent material is provided. The coated photoluminescent material includes a photoluminescent material and a uniform layer of titanium dioxide. The layer of titanium dioxide can be, for example, between about 80 nm and about 500 nm thick.

In a second aspect, a method of synthesizing a uniformly coated photoluminescent material is provided. The method includes the steps of depositing titanium dioxide for a time effective to deposit a uniform layer of titanium dioxide of a thickness of at least about 71 nm on a photoluminescent material in a single coating cycle, where the thickness can be at least about 80 nm in some embodiments. The titanium dioxide is generated from a precursor of the titanium dioxide in a liquid phase and is deposited at a rate of between about 1 nm and about 100 nm per hour, and between 3 nm to 20 nm per hour in some embodiments.

In a third aspect, a coated photoluminescent material is provided. The coated photoluminescent material can be prepared by a method which includes the steps of depositing titanium dioxide for a time effective to deposit a uniform layer of titanium dioxide of at least about 80 nm thick on a photoluminescent material in a single coating cycle. The titanium dioxide can be generated from a precursor of the titanium dioxide in a liquid phase and deposited at a rate of between about 3 nm and about 18 nm per hour.

In a fourth aspect, a solid state light emitting device is provided. The light emitting device includes a solid state light emitter, typically an LED chip, and a coated photoluminescent material. The coated photoluminescent material can be mixed with a light tranmissive binder, such as a silicone or epoxy, and the mixture applied to the light emitting surfaces of the LED chip. In alternative embodiments the coated photoluminescent material can be provided as a layer on a surface of, or incorporated within and homogeniously distributed throughout the volume of, a component that is located remotely to the LED. The coated photoluminescent material includes a photoluminescent material and a uniform layer of titanium dioxide. The layer of titanium dioxide can be, for example, between about 80 nm and about 500 nm thick.

### BRIEF DESCRIPTION OF THE DRAWINGS

FIG. 1 shows a comparison of brightness intensities between coated and uncoated green silicate phosphors, according to some embodiments.

FIG. 2 shows a comparison of photoluminescence intensities between coated and uncoated green silicate phosphors, according to some embodiments.

FIG. 3 shows a comparison of photoluminescence intensities between coated and uncoated red nitride phosphors, according to some embodiments.

FIG. 4 shows the relative brightness intensities at time intervals exceeding 1000 hrs for a green silicate phosphor, according to some embodiments.

FIG. 5 shows the relative chromaticity shift (CIE delta-x) at time intervals exceeding 1000 hrs for a green silicate phosphor, according to some embodiments.

FIG. 6 shows the relative chromaticity shift (CIE delta-y) at time intervals exceeding 1000 hrs for a green silicate phosphor, according to some embodiments.

FIG. 7 shows the relative brightness intensities at time intervals exceeding 1000 hrs for a red nitride phosphor, according to some embodiments.

FIG. 8 shows the relative chromaticity shift (CIE delta-x) at time intervals exceeding 1000 hrs for a nitride phosphor, according to some embodiments.

FIG. 9 shows the relative chromaticity shift (CIE delta-y) at time intervals exceeding 1000 hrs for a red nitride phosphor, according to some embodiments.

FIG. 10 shows a uniform titanium dioxide coating having a thickness of about 350 nm+/−about 1.4%, according to some embodiments.

FIG. 11 shows a schematic cross sectional view of a light emitting device in accordance with embodiments of the invention.

FIG. 12 shows a plan and cross sectional views of a light emitting device in accordance with embodiments of the invention.

FIGS. 13 and 14 show schematic representations of photoluminescent wavelength conversion components in accordance with embodiments of the invention.

### DESCRIPTION

The teaching provided herein is directed to photoluminescent materials which possess superior stability to heat and moisture. The teachings include a coated photoluminescent material which generally has superior stability, for example, to moisture and heat when compared to an uncoated photoluminescent material of the same composition. The superior stability of the coated photoluminescent material creates an improvement in the stability of the photoluminescence performance of the material, for example, in a light-emitting device.

As such, the teachings are directed to a reliable, photoluminescent material having a thick, uniform coating of titanium dioxide. This coated material includes a photoluminescent material and a layer comprising titanium dioxide on a surface of the photoluminescent material, the layer having a thickness ranging from about 80 nm to about 500 nm, from about 80 nm to about 450 nm, from about 100 nm to about 400 nm, from about 125 nm to about 450 nm, from about 150 nm to about 375 nm, from about 175 nm to about 350 nm, from about 200 nm to about 400 nm, from about 250 nm to about 500 nm, or any range therein. In some embodiments, the thickness of the coating can be about 80 nm, about 100 nm, about 120 nm, about 140 nm, about 160 nm, about 180 nm, about 200 nm, about 220 nm, about 240 nm, about 260 nm, about 280 nm, about 300 nm, about 320 nm, about 340 nm, about 360 nm, about 380 nm, about 400 nm, about 420 nm, about 440 nm, about 460 nm, about 480 nm, about 500 nm, or any thickness therein in about 5 nm increments.

The coatings taught herein have little-to-no effect on the light generation of the photoluminescent material. For example, an intensity and chromaticity of photoluminescence from the photoluminescent material in an uncoated form can be the same, or substantially the same, as the intensity of photoluminescence from the photoluminescent material having the layer comprising titanium dioxide.

In some embodiments, the reliability of a performance parameter of the photoluminescent coated material can be greater than that of an uncoated photoluminescent material of the same composition, where the performance reliability can be compared between materials, for example, using a measure of brightness stability, color stability, or a combination thereof, between light-emitting devices comprising the different photoluminescent materials under comparison, the light-emitting devices otherwise being the same. In other embodiments, the photoluminescence, brightness stability or color stability is greater than other coated photoluminescent materials. The term “stability” can be used, for example, to refer to a resistance to a change or deterioration of a performance parameter over a period of time, such as the intensity of an output or consistency of an output of a light-emitting device the period of time. In some embodiments, the period of time can be, for example, 1000 hrs, 1250 hrs, 1500 hrs, 1750 hrs, 2000 hrs, 3000 hrs, 4000 hrs, 5000 hrs, or 10,000 hrs under a set of operating or testing conditions used to compare the reliability of performance of the performance parameters within or between light-emitting devices.

The titanium dioxide layers can be deposited as uniform, or substantially uniform, layers. Uniformity can be expressed using any measure known to one of skill, such as a statistical measure of data obtained from measurements on a coating taught herein. A layer can be considered “uniform,” for example, where a variance in the uniformity of the layer is considered to pose little-to-no effect on the ability of the layer to protect the photoluminescent material as intended. A layer can be considered “substantially uniform” where a variance in the uniformity of the layer is considered to pose less than a substantial effect on the ability of the layer to protect the photoluminescent material as intended, such that there is only a minor effect on a performance parameter, or performance reliability, and a user of the device would believe that the layer is enhancing the reliability of the device at least substantially as intended.

The term “substantial,” in some embodiments, can be used to indicate a difference between what was sought and what was realized. In some embodiments, the difference can be more than 10%, 20%, 30%, or 35%, or any amount in-between, and the amount of the difference that may be considered insubstantial can depend on the measure under consideration. A change can be substantial, for example, where a performance characteristic was not met at least to a minimal extent sought. Likewise, the term “about,” in some embodiments, can be used to indicate an amount or variable, where differences in measures of the amount or the variable can be considered insubstantial where a difference creates less than a substantial change in a related performance characteristic.

The uniformity of a layer can be measured and compared using a percent variation from the average thickness of the layer that has been applied to the surface of the photoluminescent material. The percent variation in thickness can range, for example, from about 1% to about 33%, and any 1% increment therein, where in some embodiments, the minimum thickness of the layer is not lower than 80 nm. In some embodiments, the thickness of titanium dioxide layer varies by less than 2%. In other embodiments, the thickness of titanium dioxide layer varies by about 2%. In still other embodiments, the thickness of titanium dioxide layer varies by about 2.0 to about 2.8%, or any 0.2% increment therebetween. In still otherembodiments, the thickness of titanium dioxide layer varies by less than 3%. In still other embodiments, the thickness of titanium dioxide layer varies by less than 4%. In still otherembodiments, the thickness of titanium dioxide layer varies by less than 5%. In still other embodiments, the thickness of titanium dioxide layer varies by less than 10%. In still otherembodiments, the thickness of titanium dioxide layer varies by about 1.0 to about 10.0%, or any 0.5% increment therebetween. In still other embodiments, the thickness of titanium dioxide layer varies by less than 20%. In still other embodiments, the thickness of titanium dioxide layer varies by less than 30%. It should be appreciated that, where a percent variation exceeds an acceptable amount, the coating layer can also fall below an acceptable thickness, providing the photoluminescent material with a less-than-desirable barrier from moisture, for example.

An acceptable amount of variation will depend on the average thickness of the coating. In some embodiments, the acceptable amount of variation is that which results in a minimum thickness in the coating layer of greater than 80 nm. As such, the term “uniformity” can be used to refer to a variance in thickness measured using any method known to one of skill, for example, electron microscopy. In some embodiments, the variance in thickness can be +/−5 nm, +/−10 nm, +/−15 nm, +/−20 nm, +/−25 nm, +/−30 nm, +/−35 nm, +/−40 nm, +/−45 nm, +/−50 nm, +/−60 nm, +/−70 nm, +/−80 nm, +/−90 nm, or +/−100 nm. In some embodiments, the variance is less than 30 nm, 20 nm, 10 nm, 5 nm, 3 nm, 2 nm, or 1 nm. In some embodiments, the variance can be +/−5%, +/−10%, +/−15%, +/−20%, +/−25%, +/−30%, or +/−35%. In some embodiments, the variance is less than 30%, 20%, 10%, 5%, 3%, 2%, or 1%.

In some embodiments, the titanium dioxide layer can be between about 80 nm to about 500 nm thick. In other embodiments, the titanium dioxide layer can be between about 100 nm to about 500 nm thick. In still other embodiments, the titanium dioxide layer can be between about 200 nm to about 500 nm thick. In still other embodiments, the titanium dioxide layer can be between about 400 nm to about 500 nm thick. In still other embodiments, the titanium dioxide layer can be between about 200 nm to about 400 nm thick. In still other embodiments, the titanium dioxide layer can be between about 300 nm to about 400 nm thick. In still other embodiments, the titanium dioxide layer can be about 350 nm thick. In some embodiments, the titanium dioxide layer can have a thickness of about 100 nm, 200 nm, 300 nm, 400 nm, 500 nm, or any 10 nm increment therebetween.

In some embodiments, the size of the coated material is between about 2 μm and about 50 μm. In other embodiments, the size of the coated material is between about 5 μm and about 20 μm. The size of the coated material can be determined using any method known to one of skill.

In some embodiments, the photoluminescent material is a phosphor. In other embodiments, the photoluminescent material is a silicate phosphor, a aluminate phosphor, a nitride phosphor, a oxynitride phosphor, a sulfide phosphor or a oxysulfide phosphor. In still other embodiments, the photoluminescent material is a silicate phosphor.

In some embodiments, the phosphor is a sulfide phosphor such as, for example, (Ca, Sr, Ba)(Al, In, Ga)₂S₄:Eu, (Ca, Sr)S:Eu, CaS:Eu, (Zn, Cd)S:Eu:Ag. In other embodiments, the phosphor is a nitride phosphor such as, for example, (Ca,Sr, Ba)₂Si₅N₈:Eu, CaAlSiN₃:Eu, Ce(Ca, Sr, Ba)Si₇N₁₀:Eu or (Ca, Sr, Ba)SiN₂:Eu. Other exemplary phosphors include Ba²⁺, Mg²⁺ co-doped Sr₂SiO₄, (Y, Gd, Lu, Sc, Sm, Tb, Th, Ir, Sb, Bi)₃(Al, Ga)₅O₁₂:Ce (with or without Pr), YSiO₂N:Ce, Y₂Si₃O₃N₄:Ce, Gd₂Si₃O₃N₄:Ce, (Y, Gd, Tb, Lu)₃Al₅₋ₓSiₓO₁₂₋ₓ:Ce, BaMgAl₁₀O₁₇:Eu (with or without Mn), SrAl₂O₄:Eu, Sr₄N₄O₂₅:Eu, (Ca, Sr, Ba)Si₂N₂O₂:Eu, SrSi,Al₂O₃N₂:Eu, (Ca, Sr, Ba)Si₂N₂O₂:Eu, (Ca, Sr, Ba)SiN₂:Eu and (Ca, Sr, Ba)SiO₄:Eu (Winkler et al., U.S. Patent Application No. 2010/0283076; Lee et al., Applied Surface Science 257, (2011) 8355-8369).

In some embodiments, the phosphor is an aluminum-silicate-based orange-red phosphor with mixed divalent and trivalent cations of formula (Sr_{1-x-y}MₓT_{y})₃₋ₘEuₘ(Si_{1-z}Al_{z})O₅ where M is at least one of Ba, Mg and Zn, T is a trivalent metal, 0≦x≦0.4, 0≦y≦0.4, 0≦z≦0.2 and 0.001≦m≦0.4 (Liu et al., U.S. Patent Application No. 2008/0111472).

In other embodiments, the phosphor is a YAG:Ce phosphor of formula (Y, A)₃(Al, B)₅(O, C)₁₂:Ce³⁺ where A is selected from the group consisting of Tb, Gd, Sm, La, Sr, Ba, Ca, and where A substitutes for Y in amounts ranging from about 0.1 to 100 per cent; B is selected from the group consisting of Si, Ge, B, P and Ga, and where B substitutes for Al in amounts ranging from about 0.1 to 100 per cent; and, C is selected from the group consisting of F, Cl, N and S and where C substitutes for O in amounts ranging from about 0.1 to 100 per cent (Tao et al., U.S. Patent Application No. 2008/0138268).

In still other embodiments, the phosphor is a silicate-based yellow-green phosphor of formula A₂SiO₄:Eu²⁺D where A is Sr, Ca, Ba, Mg, Zn and Cd; and D is a dopant selected from the group consisting of F, Cl, Br, I, P, S and N (Wang et al., U.S. Pat. No. 7,311,858).

In still other embodiments, the phosphor is an aluminate-based blue phosphor of formula (M₁₋ₓEuₓ)_{2-z}Mg_{z}Al_{y})O_{[2+3/2)y} where M is at least one of Ba and Sr, (0.05<x<0.5; 3≦y≦8; and 0.8≦z≦1<1.2) or (0.2<x<0.5; 3≦y≦8; and 0.8≦z≦1<1.2) or (0.05<x<0.5; 3≦y≦12; and 0.8≦z≦1<1.2) or (0.2<x<0.5; 3≦y≦12; and 0.8≦z≦1<1.2) or (0.05<x<0.5; 3≦y≦6; and 0.8≦z≦1.2) (Dong et al., U.S. Pat. No. 7,390,437).

In still other embodiments, the phosphor is a yellow phosphor of formula (Gd₁₋ₓAₓ)(V_{1-y}B_{y})(O_{4-z}C_{z}) where A is Bi, Tl, Y, La, Ce, Pr, Nd, Pm, Sm, Eu, Tb, Dy, Ho, Er, Tm, Yb, Lu; B is Ta, Nb, W, and Mo; C is N, F, Br and I; 0<x<0.2; 0<y<0.1; and 0<z<0.1 (Li et al., U.S. Pat. No. 7,399,428).

In still other embodiments, the phosphor is a yellow phosphor of formula A[Srₓ(M₁)₁₋ₓ]_{z}SiO₄.(1-a)[Sr_{y}(M₂)_{1-y}]ᵤSiO₅:Eu²⁺D where M₁ and M₂ are are at least one of a divalent metal such as Ba, Mg, Ca, and Zn; 0.6≦a≦0.85; 0.3≦x≦0.6; 0.85≦y≦1; 1.5≦z≦2.5; and 2.6≦u≦3.3 and Eu and D are between 0.0001 and about 0.5; D is an anion selected form the group consisting of F, Cl, Br, S and N and at least some of D replaces oxygen in the host lattice (Li et al., U.S. Pat. No. 7,922,937).

In still other embodiments, the phosphor is a silicate-based green phosphor of formula (Sr,A₁)ₓ(Si,A₂)(O,A₃)₂₊ₓ:Eu²⁺ where Aₗ is at least one divalent metal ion such as Mg, Ca, Ba, Zn or a combination of +1 and =3 ions; A₂ is a 3+, 4+ or 5+ cation including at least one of B, Al, Ga, C, Ge, P; A₃ is a 1−, 2− or 3− anion including F, Cl, and Br; and 1.5≦x≦2.5 (Li et al., U.S. Patent Application No. 2009/0294731).

In still other embodiments, the phosphor is a nitride-based red phosphor of formula MₐM_{b}B_{c}(N,D):Eu²⁺ where Mₐ is a divalent metal ion such as Mg, Ca, Sr, Ba; M_{b} is trivalent metal such as Al, Ga, Bi, Y, La, Sm; M_{c} is a tetravalent element such as Si, Ge, P1, and B; N is nitrogen; and D is a halogen such as F, Cl, or Br (Liu et al., U.S. Patent Application No. 2009/0283721).

In still other embodiments, the phosphor is a silicate-based orange phosphor of formula (Sr,A₁)ₓ(Si,A₂)(O,A₃)₂₊ₓ:Eu²⁺ where Aₗ is at least one divalent metal ion such as Mg, Ca, Ba, Zn or a combination of +1 and =3 ions; A₂ is a 3+, 4+ or 5+ cation including at least one of B, Al, Ga, C, Ge, P; A₃ is a 1−, 2− or 3− anion including F, Cl, and Br; and 1.5≦x≦2.5 (Cheng et al., U.S. Pat. No. 7,655,156).

In still other embodiments, the phosphor is a aluminate-based green phosphor of formula M₁₋ₓEuₓMg_{1-y}Mn_{y}Al_{z}O_{[(x+y)+3z/2)} where 0.1<x<1.0; 0.1<y<1.0; 0.2<x+y<2.0; and 2≦z≦14 (Wang et al., U.S. Pat. No. 7,755,276).

The teachings provided herein are directed to the application of coatings comprising titanium dioxide on any of a variety of photoluminescent substrates such as, for example, those described herein. In some embodiments, the titanium dioxide can be generated from a precursor of the titanium dioxide. In some embodiments, the precursor is an organometallic compound. In other embodiments, the organometallic compound is titanium ethoxide (Ti(EtO)₄), titanium propoxide (Ti(PrO)₄), titanium isopropoxide (Ti(i-PrO)₄), titanium n-butoxide (Ti(n-BuO)₄), titanium iso-butoxide (Ti(i-BuO)₄, titanium tert-butoxide (Ti(t-BuO)₄), Tetrakis(diethylamino)titanium RCH₃CH₂)₂N]₄, Ti(AcAc)₄, Ti(CH₃)₄, Ti(C₂H₅)₄ or combinations thereof. In some embodiments, the precursor is an inorganic salt. In other embodiments, the inorganic salt is titanium oxide (TiO₂), titanium chloride (TiCl₄), titanium floride (TiF₄), titanium nitrate (Ti(NO₃)₄), titanium bromide (TiBr₄), titanium iodide (TiI₄) or titanium sulfate (TiOSO₄).

The teaching herein also provides methods for making photoluminescent materials which possess superior stability to heat and moisture. In some embodiments, the method can include depositing titanium dioxide for a time effective to deposit a uniform layer of titanium dioxide of a thickness of at least about 80 nm on a photoluminescent material in a single coating cycle. In some embodiments, the method includes depositing a layer of titanium dioxide on a surface of a photoluminescent material, where the titanium dioxide can be generated from a precursor of the titanium dioxide in a liquid phase. The depositing can occur for a time effective to create a uniform layer of the titanium dioxide to a desired thickness of at least about 80 nm on the surface of the photoluminescent material in a single coating cycle. In some embodiments, the method includes forming a mixture of the precursor and a solvent, and gradually adding water to the mixture to control (i) a rate of formation of the titanium dioxide from the precursor and (ii) a rate of deposition of the titanium dioxide on the surface of the photoluminescent material during the time effective to deposit the uniform layer. In some embodiments, the solvent can comprise water; an alcohol, such as methanol, ethanol, propanol, isopropanol, butanol, pentanol, and hexanol; acetone; methyl ethyl ketone; other hydrocarbons; or mixtures thereof.

In some embodiments, a method for synthesizing a coated photoluminescent material can include the following steps: adding a photoluminescent material to a solvent to form a first mixture; adjusting the pH of the first mixture to prepare for a hydrolysis of a titanium dioxide precursor; adding the titanium dioxide precursor to the first mixture to form a second mixture, where the precursor can be added at a controlled rate to the first mixture, and the amount of the precursor added can be such that there is less than about 10% by weight of the titanium dioxide as compared to the weight of the photoluminescent material; mixing the second mixture for a period of time to allow for a deposition of titanium dioxide on a surface of the photoluminescent material; washing the coated photoluminescent material; purifying the coated photoluminescent material; drying the coated photoluminescent material; and calcining the coated photoluminescent material.

It should be appreciated that any number of additional steps can be added to the process. For example, a coating process can include additional reaction steps, curing steps, drying steps, heat treating steps, and the like. For example, the process can include adding a mixture of water and solvent to form a third “curing” mixture; heating and/or reacting the third mixture for a second period of time; and, perhaps adding additional steps for a third period of time. In some embodiments, for example, the concentration of the photoluminescent material can be between about 0.0001 g/mL and about 10.0 g/mL.

It should be appreciated that the rate of deposition of the titanium dioxide on the surface can be controlled, to the level of an atomic layer deposition in some embodiments, using the teachings provided herein. The rate of deposition can be used in a selection of reaction time. One of skill will appreciate that the selection of reaction time will depend, at least in part, on the process design, which can include the selection of precursor, reagent concentration, reagent addition rate, reaction temperature, and desired coating thickness. These process conditions determine the rate of deposition of the titanium dioxide on the surface of the photoluminescent material. In some embodiments, the titanium dioxide is deposited at a rate of between about 1 nm and about 100 nm per hour. In some embodiments, the titanium dioxide is deposited on the photoluminescent material at a rate of between about 5 nm and about 20 nm per hour. In other embodiments, the titanium dioxide is deposited on the photoluminescent material at a rate of between about 3 nm and about 18 nm per hour. In still other embodiments, the titanium dioxide is deposited on the photoluminescent material at a rate of between about 6 nm and about 15 nm per hour. In still other embodiments, the titanium dioxide is deposited on the photoluminescent material at a rate of between about 5 nm and about 7 nm per hour. In still other embodiments, a second layer of titanium dioxide is deposited on the photoluminescent material.

In some embodiments, the concentration can be controlled through a metered addition of reactants. For example, the precursor can diluted in a solvent and water is added at a controlled rate to control hydrolysis of the precursor. In some embodiments, the precursor can be Ti(i-PrO)₄ dissolved in isopropanol, and water can be added gradually through a metered addition to control the rate of hydrolysis of the precursor. In another example, a first mixture of the photoluminescent material and a solvent can be adjusted to a desired pH in preparation for a hydrolysis of the precursor, where the precursor is then be added to the first mixture with the desired pH using a metered addition to control the rate of hydrolysis of the precursor.

The metered addition of a reactant can be achieved using any method known to one of skill. In some embodiments, the precursor can be added dropwise to a mixture containing conditions that are hydrolytic to the precursor. In some embodiments, the precursor can be continuously injected with a fine needle. In some embodiments, a hydrolytic agent, such as water or an organic solvent containing water, can be added dropwise to a mixture of a precursor and a solvent. For example, a method can include forming a mixture of the precursor and a solvent, and gradually adding water to the mixture to control (i) a rate of formation of the titanium dioxide from the precursor and (ii) a rate of deposition of the titanium dioxide on the surface of the photoluminescent material during the time effective to deposit the uniform layer.

In some embodiments, the precursor can be added at a rate of between about 0.0001 mL/min to 200 mL/min. In some embodiments, the precursor can be added at a rate of between about 2 mL/min to 30 mL/min. In some embodiments, the precursor can be added at a rate of between about 6 mL/min to 20 mL/min. In some embodiments, the precursor can be added at a rate of between about 5 mL/min to 60 mL/min.

Control of the rate of deposition provides control of the reaction time for depositing a desired thickness of a titanium dioxide layer on a surface of a photoluminescent material. Reaction times can range, for example, from 0.1.0 hrs to 10 days, from 1.0 hr to 7 days, from 2 hrs to 5 days, from 1.0 hr to 4 days, from 0.5 hrs to 3 days, from 0.5 hrs to 2 days, from 0.5 hrs to 1 day, from 1.0 hr to 18 hrs, from 0.5 hrs to 12 hrs, from 0.5 hrs to 8 hrs, from 1.0 hrs to 6 hrs, from 0.5 hrs to 4 hrs, from 0.5 hrs to 2 hrs, or any range therein.

In some embodiments, a reaction mixture can be heated to a temperature that ranges from about 30° C. to the boiling point of the solvent +/−10° C. In other embodiments, the reaction mixture can heated to a temperature of between about 40° C. and about 80° C. It should be appreciated that the terms “react,” “reacting,” and “reaction” can be used in some embodiments to refer to, for example, hydrolyzing a precursor to form titanium dioxide, depositing a layer of the titanium dioxide on a surface of a photoluminescent material, and the like, where a change in bonding between molecular structures can occur during that step in the process.

In some embodiments, the coated photoluminescent material can be purified. For example, the coated photoluminescent material can be purified by washing with a solvent, followed by a filtration. In other embodiments, the coated photoluminescent material can be purified by centrifugation, sedimentation and decanting. Any method of purification known to one of skill can be used.

In some embodiments, the coated photoluminescent material can be dried at a temperature of between about 60° C. and about 200° C. In other embodiments, the coated photoluminescent material can be dried at a temperature of between about 85° C. and about 200° C. And, in some embodiments, the drying can include vacuum-drying, freeze-drying, or critical point drying. In still other embodiments, the coated photoluminescent material can be calcined at a temperature between about 200° C. and about 600° C.

Other methods for synthesizing the coated photoluminescent material are provided herein. The photoluminescent material is added to a solvent to form a first mixture. The pH of the first mixture is adjusted to react with an inorganic precursor of titanium dioxide. The precursor is added at a controlled rate to the first mixture to form a second mixture, where the amount of the precursor added is less than about 10% by weight of the photoluminescent material. The second mixture is heated for a period of time and then reacted for a second period of time. The coated photoluminescent material is purified, dried and then calcined. In some embodiments, the second mixture is heated at a temperature of between about 40° C. and about 80° C. and for a period of time between about 0.1 hours and about 10 days. In other embodiments, the second mixture is reacted for a second period of time between about 0.1 hours and about 10 days.

In some embodiments, light emitting diode device is provided. The light emitting diode device includes a chip and a coated photoluminescent material. The coated photoluminescent material includes a photoluminescent material and a uniform layer of titanium dioxide. The layer of titanium dioxide is between 80 nm and 500 nm thick. In some embodiments, the device has a higher brightness stability and color stability than a second device having the light-emitting diode chip and the photoluminescent material in an uncoated form. The brightness stability and the color stability can be tested and compared, for example, over a period of operation of at least 1000 hrs. In some embodiments, the device has a thickness of the titanium dioxide layer that ranges from between about 200 nm to about 500 nm. In this embodiment, the device has a higher brightness stability and color stability than a second device comprising the light-emitting diode chip and the photoluminescent material in an uncoated form. In some embodiments, a titanium dioxide coating can range from 71 nm to 500 nm. The thickness of the titanium dioxide layer is at least 80 nm, 90 nm, or 100 nm, in some embodiments, for example; and about 200 nm, about 300 nm, about 400 nm, or about 500 nm in other embodiments, for example. As such, the light-emitting devices provided by the teachings herein can have brightness stability or color stability that exceeds that of other such devices comprising coated photoluminescent materials. The brightness stability and the color stability can again be tested over a period of operation of at least 1000 hrs.

### EXAMPLE 1

### Selection of a Titanium Dioxide Precursor

The coating process is a liquid process that can use an organometallic precursor of titanium dioxide or an inorganic precursor of titanium dioxide. The type of precursor chosen will affect the choice of solvent, reaction temperature, and reaction time, and the rate of addition of reactants. Organometallic or inorganic precursors of titanium dioxide can be used.

The use of an organometallic precursor will generally include first dispersing the precursor in a water-free, or substantially water-free solvent medium. This avoids the occurrence of an undesirable hydrolytic reaction of the precursor before deposition can occur on a surface of the photoluminescent material. For example, in a process that uses an organometallic precursor, which hydrolyzes upon contact with water, isopropyl alcohol can be obtained in a relatively pure form, free of water, so it's a good candidate solvent for generally all of the organometallic precursors, for example.

The choice of precursor selection can be based on process control conditions. For example, if we choose titanium n-butoxide or the titanium isopropoxide, for example, we know they hydrolyze in water very fast, so we control water concentration in an alcohol solvent, such as by adding water to the isopropyl alcohol, to control reaction rate. On the other hand, an inorganic precursor can be selected and dispersed in water directly as a primary solvent, for example, and then pH is gradually made more basic, such as through addition of ammonia, to control reaction rate.

### EXAMPLE 2

### General Procedure for Making a Titanium Dioxide Coated Photoluminescent Material

This example describes a general method of making a coated photoluminescent material. The method includes selecting (i) process components, such as a photoluminescent material (“phosphor”), a titanium dioxide precursor, and a solvent; and (ii) process conditions, such as component concentrations, rate of addition of reactants, temperature of reaction, and reaction time.

After the process components have been selected, the process conditions can be selected using methods known to one of skill. For example, one of skill would know how to design an array of process conditions that have varying reactant concentrations and rates of addition, and reaction temperatures. Note that a concentration of less than 10% total titanium dioxide per weight of phosphor (wt/wt) should be used in each sample to drive deposition of the titanium dioxide on the surface of the phosphor. The selection of the amount of titanium dioxide to add for the deposition reaction can vary with the amount of phosphor and phosphor size. An average phosphor particle size can range, for example, from about 2 μm to about 30 μm in diameter, and the average diameter can be about 12 μm to about 20 μm for the green silicate phosphors, for example. Actual size distributions can range from about 1 um to about 100 um across a variety of phosphor types. The rates of addition can include, for example, adding a “hydrolytic agent” such as water or another water-containing solvent (ethanol, for example), at a controlled rate in each sample in the array, while also varying temperature and reaction time across the array. Stir and wait for the end of a selected reaction time to get the coating thickness we want. Each coated phosphor across the array is tested for reliability of performance in a light-emitting device, where the highest reliabilities suggest

Using the select process components and conditions, mix the phosphor, the titanium dioxide precursor, and the solvent together to form a first mixture. Heat the first mixture to the select reaction temperature, add the select hydrolytic agent such as water or another water-containing solvent (e.g. ethanol) at a controlled rate to the first mixture to control the rate of hydrolysis of the precursor. This also provides control over the rate of deposition of the titanium dioxide on the phosphor. Stir for the select reaction time to obtain the desired coating thicknesses.

The combination of thick coatings and a high level of uniformity (low variance in thickness) correlates with a high reliability of a coated phosphor in a light-emitting device. Balancing coating thickness with uniformity has shown to result in a stable, energy output of the phosphor through the protective coating to provide a reliable, light-emitting device.

### EXAMPLE 3

### Select Process Components and Conditions for Titanium Dioxide Coating of a Green Silicate and a Red Nitride Phosphor

A green silicate phosphor was coated in this example (“green 1”). Green 1 is of the class represented by the formula (Sr_{1-x-y} Baₓ Mg_{y})₂SiO₄Cl_{z}:Eu; where 0≦x≦1, 0≦y≦0.5, and 0≦z≦0.5.

To a glass reactor with heating mantle and stirring, isopropyl alcohol (IPA, 3.0 L) was added. Then green 1 (200 g) was added with stirring to form a suspension. Titanium n-butoxide (30 mL) was added to the suspension by syringe. The suspension was stirred 2.0 hours at room temperature. A mixture of de-ionized water and isopropyl alcohol (20 mL:20 mL) was added dropwise to the suspension. After addition, the resultant suspension was heated to 40° C. for 0.5 hour. It was allowed to cool to room temperature and stirred further for 20 hours at room temperature. The suspension was heated to 60° C. for 1.5 hours and further stirred for 22 hours at room temperature. Then a second portion of de-ionized water and isopropyl alcohol (80 mL:50 mL) was added dropwise to the suspension. The suspension was heated 1.0 hour at 40° C. and stirred for a further 2.5 hours at room temperature. The stirring assembly was removed. The mixture settled for 10 minutes. The top layer of the solution was decanted and more IPA was added to wash 2 times before filtering through a Büchner funnel. The solid in the funnel was dried in a vacuum oven at 110° C. for 1.0 hours. After drying, the coated phosphor was fired in a box furnace at 350° C. for 1.0 hour.

A red nitride phosphor was also coated in this example (“red 1”). Red 1 is of the class represented by the formula (Ca₁₋ₓSrₓ)SiN₃:Eu, where 0≦x≦1.

To a glass reactor with heating mantle and stirring bar, isopropyl alcohol (IPA, 280 mL) was added. Then red 1 (10 g) was added with stirring to form a suspension. Titanium n-butoxide (1.5 mL) was added to the suspension by syringe. The suspension was stirred 2.0 hours at room temperature. A mixture of de-ionized water and isopropyl alcohol (2 mL:20 mL) was added dropwise to the suspension. The resultant suspension was heated to 40° C. for 0.5 hour. It was allowed to cool to room temperature and stirred further for 20 hours at room temperature. The suspension was heated to 60° C. for 1.5 hours and stirred for 22 additional hours at room temperature. Then, a second portion of de-ionized water and isopropyl alcohol (4 mL:20 mL) was added dropwise to the suspension. The suspension was heated 1.0 hour at 40° C. and stirred further for 2.5 hours at room temperature. The stiffing bar was removed, and the mixture settled for 10 minutes. The top layer of the solution was decanted and more IPA was added to wash two times before filtering through a Büchner funnel. The solid in the funnel was dried in a vacuum oven at 110° C. for 1.0 hours. After drying, the coated phosphor was fired in a box furnace at 350° C. for 1.0 hour.

### EXAMPLE 4

### Comparing Brightness and Photoluminescence Intensities Between Coated and Uncoated Phosphors

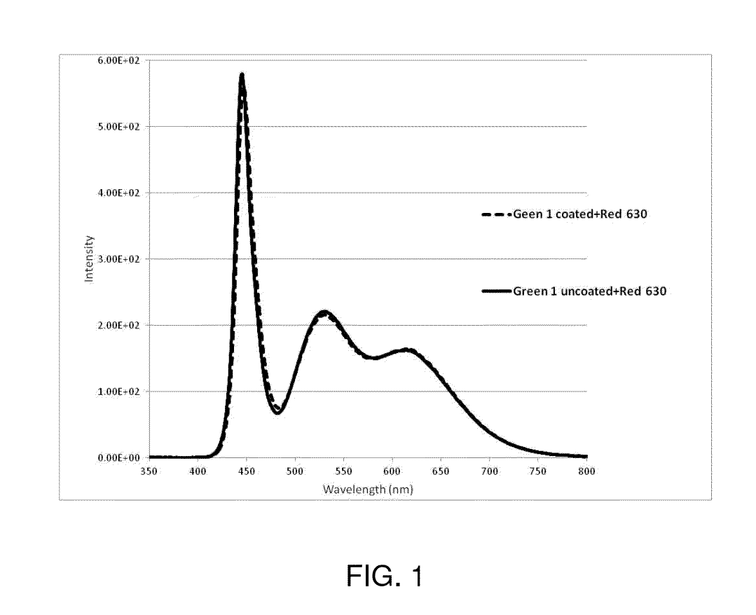

FIG. 1 shows a comparison of brightness intensities between coated and uncoated green silicate phosphors, according to some embodiments. Green 1 was mixed with a red phosphor, red 630, in light transmitting binder to get white light (x=0.30, and y=0.30). The mixed gel was put into an LED chip and cured. The device was operated under blue light and brightness was measured. It can be seen that the coating didn't create a substantial reduction in the brightness intensity of the LED device with the green silicate phosphor. Table 1 further shows that there was no substantial loss in intensity from the coating.

TABLE 1

| Name | Green 1(Coated) + Red 630 | Green 1(Uncoated) + Red 630 |
|---|---|---|
| Ratio | G/R = 73/27 | G/R = 72.5/27.5 |
| Brightness | 8.671E−03 | 8.793E−03 |
| CRI(Ra) | 89.4 | 87.5 |
| R9 | 90.8 | 97.6 |

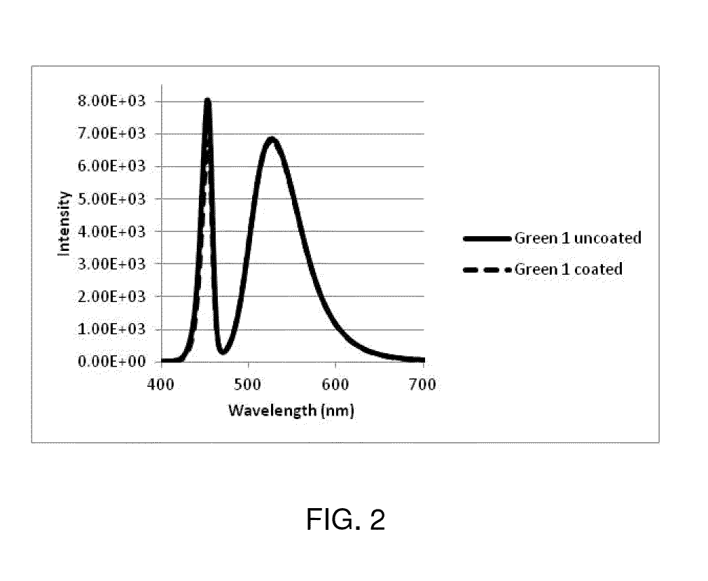

FIG. 2 shows a comparison of photoluminescence intensities between coated and uncoated green silicate phosphors, according to some embodiments. Green 1 was put into a shallow dish and tampered down to make a flat surface. The phosphor is then excited by and external light source (Blue LED) and then emission spectrum was measured. As can be seen in FIG. 2, there was no substantial loss in photoluminescence due to the coating.

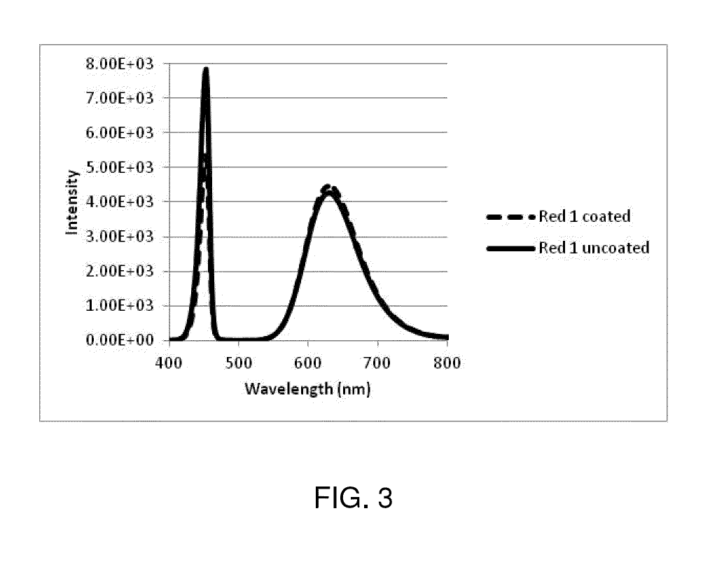

FIG. 3 shows a comparison of photoluminescence intensities between coated and uncoated red nitride phosphors, according to some embodiments. Red 1 was put into a shallow dish and tampered down to make a flat surface. The phosphor is then excited by and external light source (Blue LED) and then emission spectrum was measured. As can be seen in FIG. 3, there was no substantial loss in photoluminescence due to the coating.

### EXAMPLE 5

### Reliability Testing of Light-Emitting Devices Having Phosphors Coated with Titanium Dioxide.

Green 1 was mixed with a light transmitting binder. The mixed gel was put into LED chip and cured. The packaged device was placed in an oven at 85° C. and 85% humidity and operated continuously. At different time intervals, the device was removed from oven and emission spectra were measured by excitation with blue light. The data were collected to calculate color change and brightness.

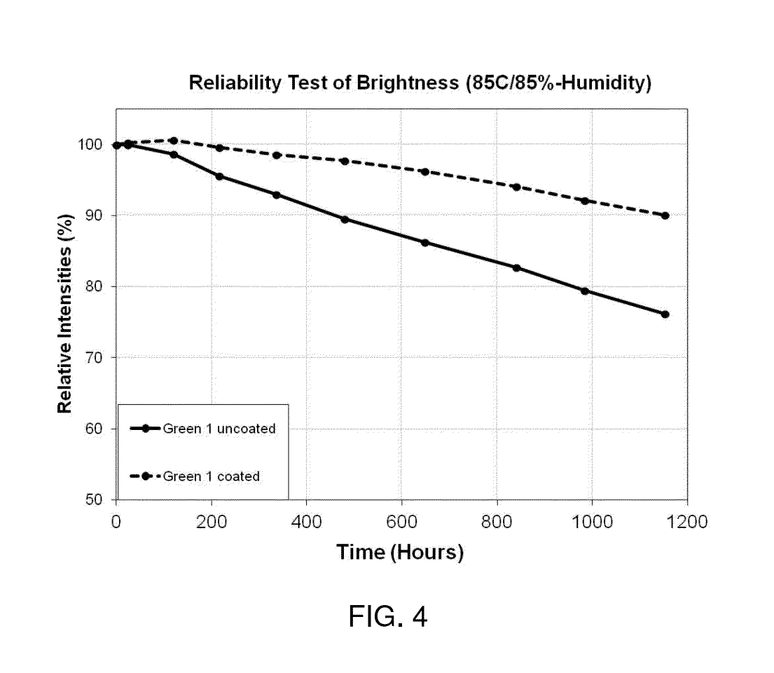

FIG. 4 shows the relative brightness intensities at time intervals exceeding 1000 hrs for a green silicate phosphor, according to some embodiments. As shown in FIG. 4, a high level of brightness stability was observed for the light-emitting device having the titanium dioxide coated phosphor when compared to the uncoated phosphor.

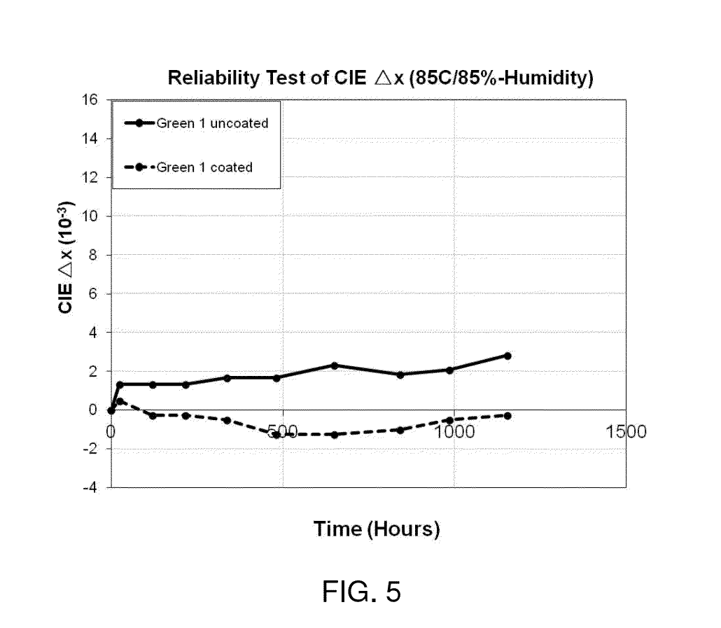

FIG. 5 shows the relative chromaticity shift (CIE delta-x) at time intervals exceeding 1000 hrs for a green silicate phosphor, according to some embodiments. As shown in FIG. 5, a high color stability was observed for the light-emitting device having the titanium dioxide coated phosphor when compared to the uncoated phosphor.

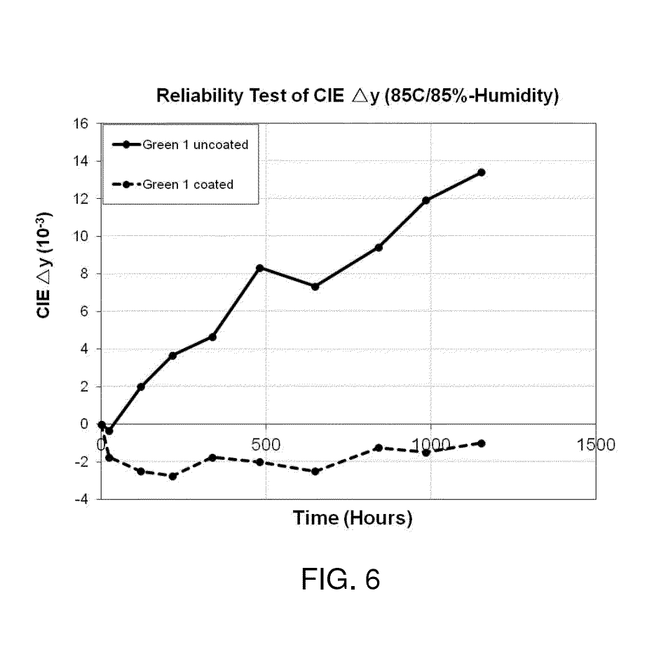

FIG. 6 shows the relative chromaticity shift (CIE delta-y) at time intervals exceeding 1000 hrs for a green silicate phosphor, according to some embodiments. As shown in FIG. 6, a high color stability was observed for the light-emitting device having the titanium dioxide coated phosphor when compared to the uncoated phosphor.

Red 1 was mixed with a light transmitting binder. The mixed gel was put into an LED chip and cured. The packaged device was placed in a oven at 85° C. and 85% humidity and operated continuously. At different time intervals, the device was removed from the oven and emission spectra were measured by excitation with blue light. The data were collected to calculate color change and brightness.

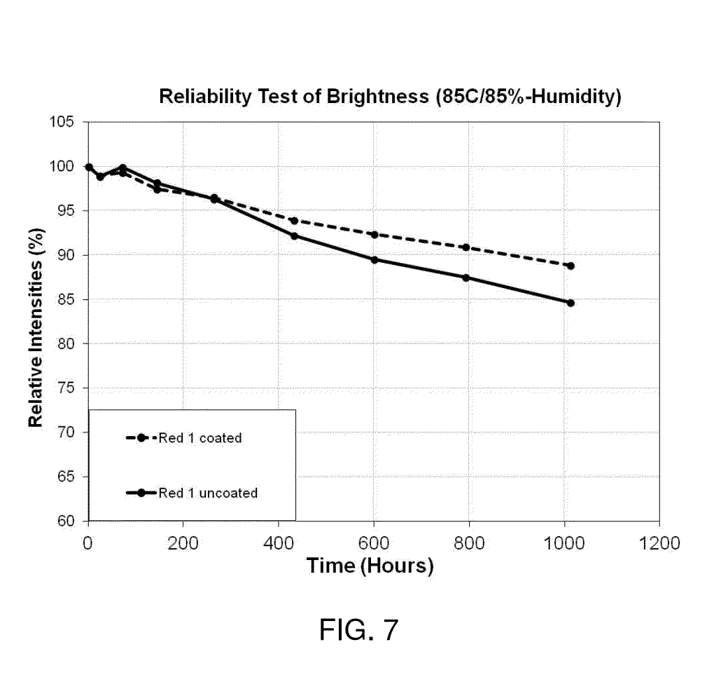

FIG. 7 shows the relative brightness intensities at time intervals exceeding 1000 hrs for a red nitride phosphor, according to some embodiments. As shown in FIG. 7, a high level of brightness stability was observed for the light-emitting device having the titanium dioxide coated phosphor when compared to the uncoated phosphor.

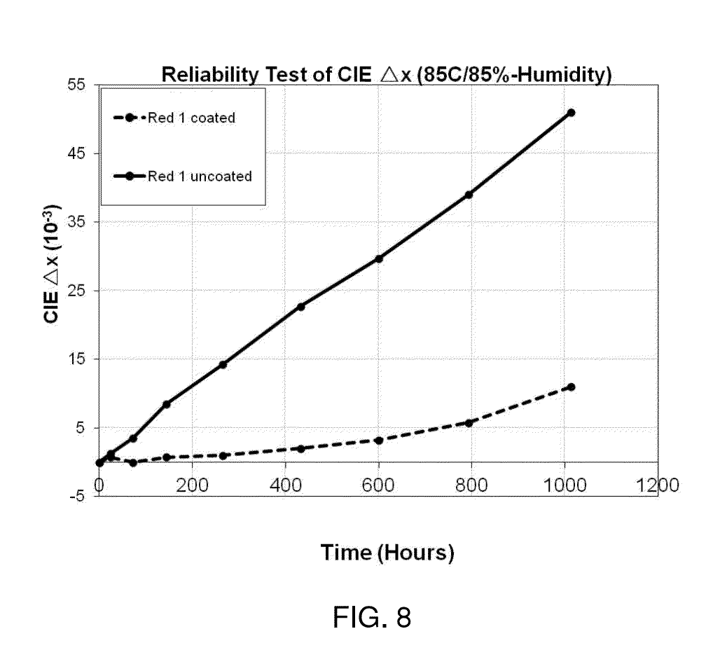

FIG. 8 shows the relative chromaticity shift (CIE delta-x) at time intervals exceeding 1000 hrs for a nitride phosphor, according to some embodiments. As shown in FIG. 8, a high color stability was observed for the light-emitting device having the titanium dioxide coated phosphor when compared to the uncoated phosphor.

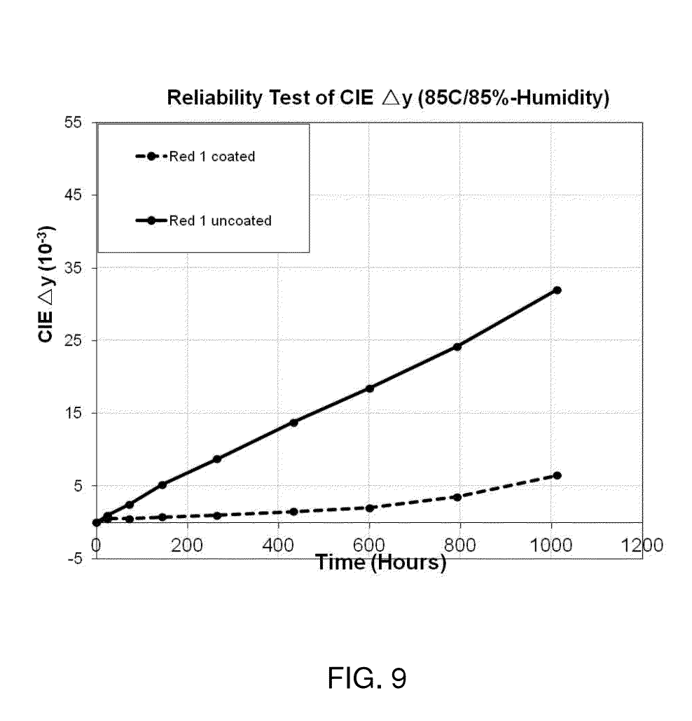

FIG. 9 shows the relative chromaticity shift (CIE delta-y) at time intervals exceeding 1000 hrs for a red nitride phosphor, according to some embodiments. As shown in FIG. 9, a high color stability was observed for the light-emitting device having the titanium dioxide coated phosphor when compared to the uncoated phosphor.

### EXAMPLE 6

### Determining Thickness and Uniformity of Titanium Dioxide Layer

In accordance with the general teachings of Example 2 above, each sample was tested for reliability, and the sample having the highest reliability was assumed to correlate with the best set of conditions. A combination of coating uniformity and thickness were found to be elements of a coated phosphor that contributed to a light-emitting device having a high reliability. The balance between thickness and uniformity was found to be important to obtain the desired energy output of the phosphor and sealant ability of the coating to protect the phosphor.

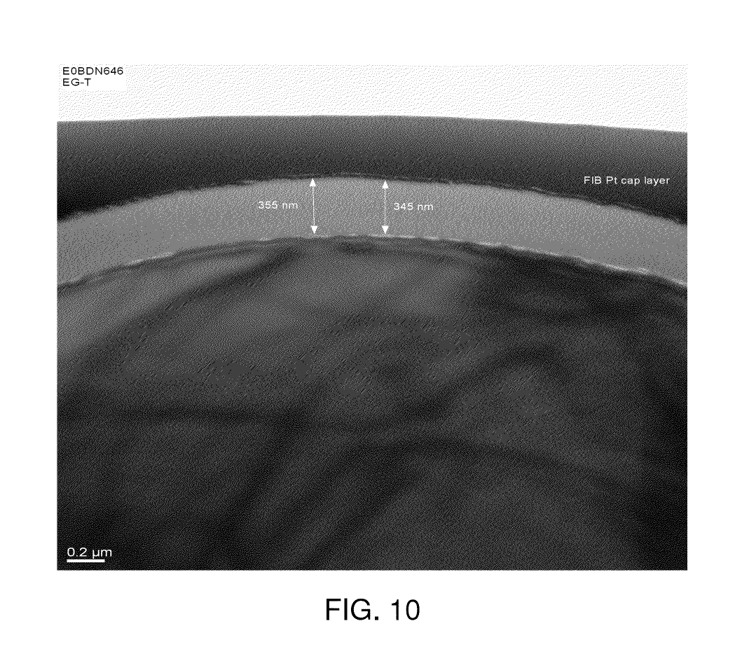

FIG. 10 shows a uniform titanium dioxide coating having a thickness of about 350 nm+/−about 1.4%, according to some embodiments. A TEM-ready sample was prepared from each powder using the in situ FIB lift out technique on an FEI Dual Beam 830 FIB/SEM. The area of the particle to be cross sectioned was first capped with protective layers of Iridium and platinum. These layers protect the coating surface during the FIB milling process. The TEM-ready samples were imaged with a FEI Tecnai TF-20 FEG/TEM operated at 200 kV in bright-field (BF) TEM mode and high resolution (HR) mode. Measurements were taken to determine the thickness and uniformity of thickness, where the thickness ranged from 345 nm to 355 nm, and an average of about 350 nm, providing a coating having a high level of uniformity with an estimated variance of about +/−1.4%.

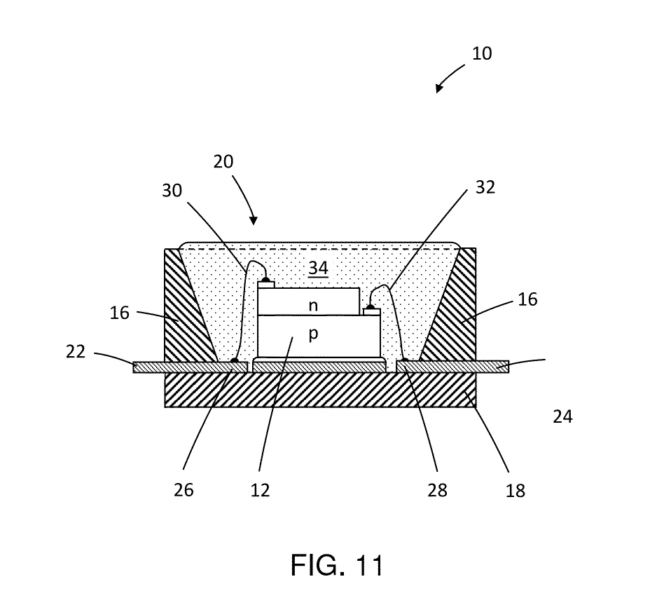

An example of a light emitting device 10 in accordance with embodiments of the invention is shown in FIG. 11. The device can comprise a blue light emitting GaN (gallium nitride) LED chip 12 housed within a package 14. The package 14, which can for example comprise a low temperature co-fired ceramic (LTCC) or high temperature polymer, comprises upper and lower body parts 16, 18. The upper body part 16 defines a recess 20, often circular in shape, which is configured to receive the LED chips 12. The package 14 further comprises electrical connectors 22, 24 that also define corresponding electrode contact pads 26, 28 on the floor of the recess 20. Using adhesive or soldering the LED chip 12 is mounted to the floor of the recess 20. The LED chip's electrode pads are electrically connected to corresponding electrode contact pads 26, 28 on the floor of the package using bond wires 30, 32 and the recess 20 is completely filled with a transparent polymer material 34, typically a silicone, which is loaded with the powdered coated phosphor material such that the exposed surfaces of the LED chip 12 are covered by the phosphor/polymer material mixture. To enhance the emission brightness of the device the walls of the recess are inclined and have a light reflective surface.

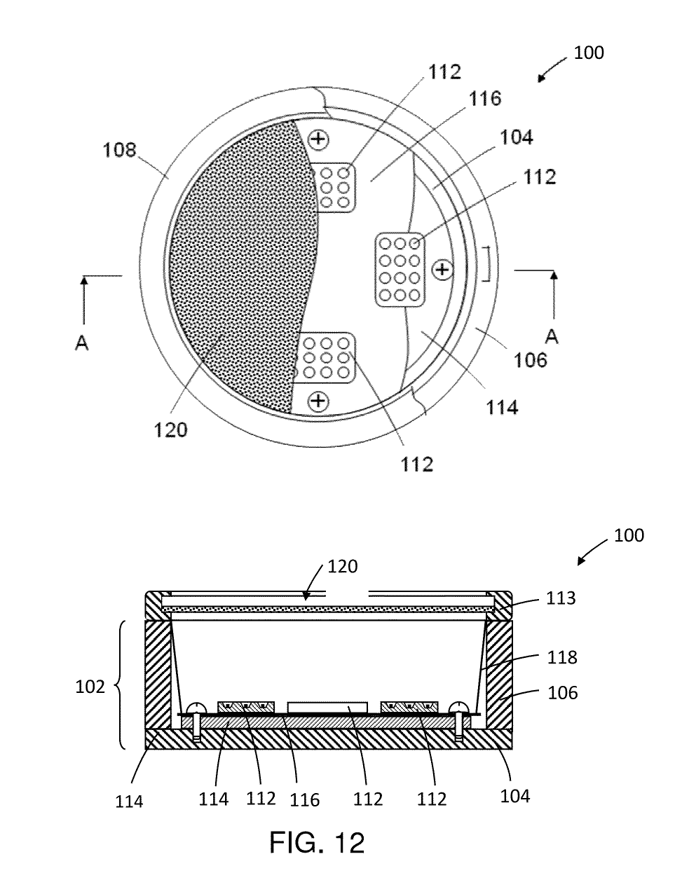

A solid-state light emitting device 100 in accordance with an embodiment of the invention will now be described with reference to FIG. 12 which shows schematic partial cutaway plan and sectional views of the device. The device 100 is configured to generate warm white light with a CCT (Correlated Color Temperature) of approximately 3000K and a luminous flux of approximately 1000 lumens and can be used as a part of a downlight or other lighting fixture.

The device 100 comprises a hollow cylindrical body 102 composed of a circular disc-shaped base 104, a hollow cylindrical wall portion 106 and a detachable annular top 108. To aid in the dissipation of heat the base 104 is preferably fabricated from aluminum, an alloy of aluminum or any material with a high thermal conductivity. As indicated in FIG. 12 the base 104 can be attached to the wall portion 106 by screws or bolts or by other fasteners or by means of an adhesive.

The device 100 further comprises a plurality (four in the example illustrated) of blue light emitting LEDs 112 (blue LEDs) that are mounted in thermal communication with a circular-shaped MCPCB (metal core printed circuit board) 114. The blue LEDs 112 can comprise a ceramic packaged array of twelve 0.4 W GaN-based (gallium nitride-based) blue LED chips that are configured as a rectangular array 3 rows by 4 columns

To maximize the emission of light, the device 100 can further comprise light reflective surfaces 116, 118 that respectively cover the face of the MCPCB 114 and the inner curved surface of the top 108. The device 100 further comprises a photoluminescent wavelength conversion component 120 that is operable to absorb a proportion of the blue light generated by the LEDs 112 and convert it to light of a different wavelength by a process of photoluminescence. The emission product of the device 100 comprises the combined light generated by the LEDs 112 and the photoluminescent wavelength conversion component 120. The wavelength conversion component is positioned remotely to the LEDs 112 and is spatially separated from the LEDs. In this patent specification “remotely” and “remote” means in a spaced or separated relationship. The wavelength conversion component 120 is configured to completely cover the housing opening such that all light emitted by the lamp passes through the component 120. As shown the wavelength conversion component 120 can be detachably mounted to the top of the wall portion 106 using the top 108 enabling the component and emission color of the lamp to be readily changed.

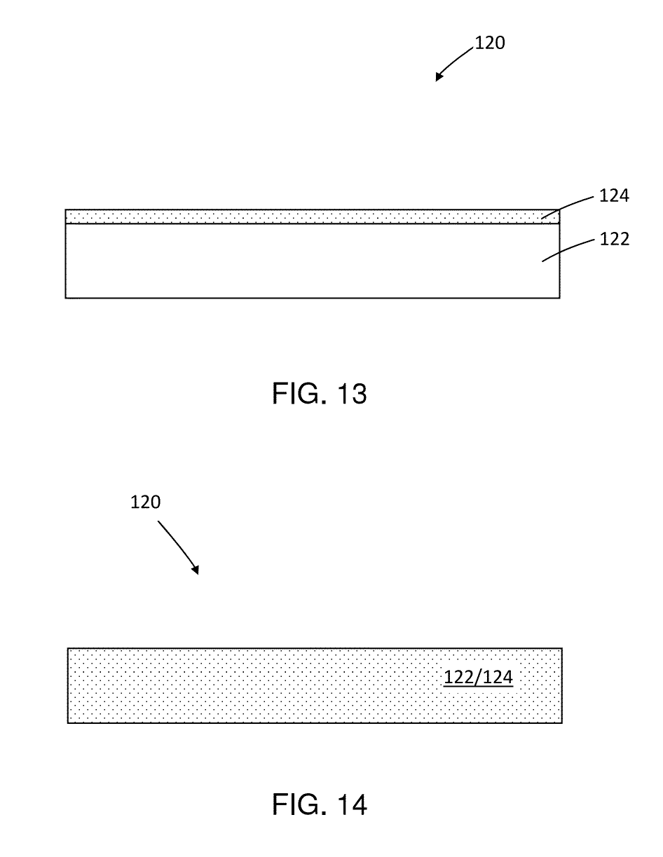

As shown in FIG. 13, the wavelength conversion component 120 comprises, in order, a light transmissive substrate 122 and a wavelength conversion layer 124 containing one or more coated photoluminescent materials. The light transmissive substrate 122 can be any material that is substantially transmissive to light in a wavelength range 380 nm to 740 nm and can comprise a light transmissive polymer such as a polycarbonate or acrylic or a glass such as a borosilicate glass. For the device 100 of FIG. 12 the substrate 122 comprises a planar circular disc of diameter ψ=62 mm and thickness t1 which is typically 0.5 mm to 3 mm. In other embodiments the substrate can comprise other geometries such as being convex or concave in form such as for example being dome shaped or cylindrical.

The wavelength conversion layer 124 is deposited by thoroughly mixing the coated photoluminescent material in known proportions with a liquid light transmissive binder material to form a suspension and the resulting phosphor composition, “phosphor ink”, deposited directly onto the substrate 122. The wavelength conversion layer can be deposited by screen printing, slot die coating, spin coating or doctor blading.

In alternative embodiments as indicated in FIG. 14 the coated photoluminescent material can be incorporated in the wavelength conversion component and homogenously distributed throughout the volume of the component.

It should be noted that there are alternative ways of implementing the teaching herein. Accordingly, the present embodiments are to be considered as illustrative and not restrictive, and the invention is not to be limited to the details given herein, but may be modified within the scope and equivalents of the appended claims. Depending on the coating material composition, in particular the index of refractive of the coating material, can affect the coating thickness that is desired. For example, for the titanium dioxide coatings taught herein, the coating thickness can range from about 80 nm to about 500 nm, providing photoluminescent materials which possess superior stability to heat and moisture. The coating material can be applied to the photoluminescent material using liquid phase deposition using a precursor of the coating material in a liquid phase such as an organometallic or organic precursor. The rate of deposition of the coating can be controlled to a rate of between about 1 nm and about 100 nm per hour, in some embodiments, enabling a thick coating to be deposited in a single process, for example, in about 10 hours to 72 hours. As can be seen from the teachings herein, the deposition rate can be controlled. For example, the deposition rate can be controlled by the precursor concentration, addition rate of the precursor and/or the temperature of the process. By analogy with gas phase atomic layer deposition (ALD), embodiments taught herein can be considered to be a liquid atomic layer growth method that enables much thicker coatings of material to be deposited on a photoluminescent material. And, although particularly surprising results have been shown using the coatings and substrates taught herein, it is contemplated that beneficial results may also be obtainable using the coatings and methods taught herein on any of a variety of photoluminescent materials.

All publications and patents cited herein are incorporated by reference in their entirety.

What is claimed is:

1. A photoluminescent material having a thick, uniform coating of titanium dioxide, comprising a photoluminescent material; and
a layer comprising titanium dioxide on a surface of the photoluminescent material;
wherein, the thickness of the titanium dioxide layer ranges from about 80 nm to about 500 nm.

2. The material of claim 1, wherein intensity of photoluminescence from the photoluminescent material in an uncoated form is the same, or substantially the same, as the intensity of photoluminescence from the photoluminescent material having the layer comprising titanium dioxide.

3. The material of claim 1, wherein the thickness of the titanium dioxide layer ranges from about 200 nm to about 500 nm.

4. The material of claim 1, wherein the thickness of the titanium dioxide layer varies by less than about 2%.

5. The material of claim 1, wherein the titanium dioxide layer ranges from about 300 nm to about 400 nm.

6. The material of claim 1, wherein the titanium dioxide layer is about 350 nm thick.

7. The material of claim 1, comprising a silicate phosphor, an aluminate phosphor, a nitride phosphor, a oxynitride phosphor, a sulfide phosphor or a oxysulfide phosphor.

8. The material of claim 1 comprising a silicate phosphor.

9. A method of synthesizing a uniformly coated photoluminescent material, comprising depositing a layer of titanium dioxide on a surface of a photoluminescent material, wherein:
the titanium dioxide is generated from a precursor of the titanium dioxide in a liquid phase;
the depositing occurs for a time effective to deposit a uniform layer of the titanium dioxide to a thickness of at least about 80 nm on the surface of the photoluminescent material in a single coating cycle; and,
the titanium dioxide is deposited on the surface at a rate of between about 1 nm and about 100 nm per hour.

10. The method of claim 9, wherein the depositing comprises
forming a mixture of the precursor and a solvent; and
gradually adding water to the mixture to control (i) a rate of formation of the titanium dioxide from the precursor and (ii) a rate of deposition of the titanium dioxide on the surface of the photoluminescent material during the time effective to deposit the uniform layer.

11. The method of claim 9, wherein the titianium dioxide is deposited at a rate of between about 3 nm and about 15 nm per hour.

12. The method of claim 9, wherein the precursor is an organometallic compound.

13. The method of claim 9, wherein the precursor is an inorganic salt.

14. A coated photoluminescent material synthesized by the method of claim 9.

15. The coated photoluminescent material of claim 14, wherein intensity of photoluminescence from the photoluminescent material in an uncoated form is the same, or substantially the same, as the photoluminescent material having the layer comprising titanium dioxide.

16. A light emitting device, comprising:
a solid state light emitter; and
the coated photoluminescent material of claim 1.

17. The light emitting device of claim 16 comprising a silicate phosphor.

18. The light emitting device of claim 16 comprising a nitride phosphor.

19. A light emitting device, comprising
a solid-state light emitter; and
a coated photoluminescent material including a uniform layer of titanium dioxide on a surface of a photoluminescent material;
wherein, the thickness of the titanium dioxide layer ranges from between about 200 nm to about 500 nm.

20. The light emitting diode of claim 19 comprising a silicate phosphor.
